(19) United States
(12) Patent Application Publication
(10) Pub. No.: US 2008/0082869 A1
(43) Pub. Date: Apr. 3, 2008

(54) MEMORY CONTROL UNIT

(75) Inventor: Jun Sugawara, Kawasaki (JP)

Correspondence Address: KATTEN MUCHIN ROSENMAN LLP, 575 MADISON AVENUE, NEW YORK, NY, 10022-2585, US

(73) Assignee: FUJITSU LIMITED, Kawasaki-shi (JP)

(21) Appl. No.: 11/861,524

(22) Filed: Sep. 26, 2007

(30) Foreign Application Priority Data
Sep. 29, 2006 (JP) 2006-268371

(51) Int. Cl. G11C 29/00

(52) U.S. Cl. 714/702

(57) ABSTRACT

The address specified from an upper-level unit is divided into a Bank address, a Row address and a Column address. Parity bits are separately generated to the Row address and the Column address supplied in a time division multiplexed manner, and check bits are generated based on the both parity bits and the data concerned. With this, in addition to a case when a one-bit error is produced in either the Row address or the Column address, it is possible to detect as a two-bit error even when bit errors are produced in both the Row address and the Column address.

### CROSS-REFERENCE TO RELATED APPLICATIONS

This application is based upon and claims the benefit of priority from the prior Japanese Patent Application No. 2006-268371, filed on Sep. 29, 2006, the entire contents of which are incorporated herein by reference.

### BACKGROUND OF THE INVENTION

1. Field of the Invention

The present invention relates to a memory control unit for controlling a memory being mounted on a communication apparatus, a control apparatus, or an information processing apparatus, etc., and more particularly a memory control unit for a memory of which address is specified by at least two addresses.

2. Description of the Related Art

As methods for detecting a memory error, a method of using a parity bit, a method of using ECC (Error Correcting Code), etc., are known. In the method of using the parity bit, the bit values of a data string is summed up, and the least significant bit (parity bit) of the summation result is added to the data, so as to be recorded as a redundant bit. When the data is read out, the least significant bit in the summation result of each bit value in the above data is compared with the recorded parity bit. When the both values do not match, an error is detected as a memory error.

Memory error detection by use of the parity bit has a merit of very simple detection processing with a small number of redundant bits. However, although the presence of the error can be detected, it is neither possible to detect the bit position in which the error is produced, nor to correct the error.

In contrast, the method of using ECC generates check bits (ECC) of, for example, 8 bits to a 64-bit data, so as to record into a memory together with the data. At the time the data is read out from the memory, when a one-bit error is detected by comparing check bits generated from the readout data with the recorded check bits, the position of the error bit is identified, and the error can be corrected. Further, when errors are produced simultaneously in two or more bits, it is possible to detect the presence of the two or more bit error, although it is not possible to correct the error.

The number of bits required for the check bits (ECC) is determined from Hamming Code. When a data string has N bits, the number of check bits is determined by taking the logarithm of N to the base 2, and by adding 2 thereto. Therefore, check bits constituted of six bits for a string of 16-bit data, seven bits for 32-bit data, and eight bits for 64-bit data are required, respectively.

The method of using ECC requires an increased number of redundant bits, and produces an expensive cost because of complicated processing for error detection and correction. However, because a memory error may cause a fatal system failure with high possibility, such the memory check function is essential in a system such as a base station control apparatus in radio communication, which produces serious influences in the event of a memory failure.

Now, at the time of storing a data, even if no data error is produced, an address error causes the data to be recorded to an incorrect address. Also, at the time of reading out the data, an address error causes the data to be read out from an incorrect address. In both the above cases, the specified data cannot be read out correctly. If the data of a different address is read out, malfunction of program operation, runaway, etc. possibly occur. However, since there is no error in the data, the error is not detected by the comparison using the check bits (ECC). Accordingly, there are cases in which the check bits are generated in consideration of address, as well as data.

Specifically, a one-bit parity bit is generated to an address specified from an upper-level unit, and check bits are generated to a bit string that combines the data bit string concerned with the above parity bit. At the time of data readout, the check bits recorded in the memory is compared with check bits generated using both the parity bit generated from the specified address and the readout data. Thus, it is possible to detect an error against the parity bit.

In the Patent documents (1) the official gazette of the Japanese Unexamined Patent Publication No. Hei-7-105102, and (2) the official gazette of the Japanese Unexamined Patent Publication No. Hei-4-372800, memory control units performing error detection using check bits in consideration of a parity bit are disclosed.

Now, there arises a problem as described below in case of a memory, such as a DRAM (Dynamic Random Access Memory), which requires at least the address designation of a Row address and a Column address to specify a particular address in the memory, and to which the above Row address and the Column address are supplied through an identical signal line (among a plurality of signal lines) in a time division multiplexed manner.

Namely, when the address specified by an upper-level unit is divided into the Row address and the Column address, and when the Row address and the Column address are supplied in mutually different timing through the identical signal line, a two-bit error is produced on the occurrence of errors in both the Row address and the Column address. Accordingly, the address error cannot be detected when using one parity bit.

More specifically, in case that a failure occurs on one signal line, producing continuous “0” of the signal line, when the bit values of the Row address and the Column address supplied on the signal line of interest are “1”, errors are produced on both the Row address and the Column address. Therefore, in regard to address, it is desirable that a two or more bit error can be detected.

### SUMMARY OF THE INVENTION

Accordingly, it is an object of the present invention to provide a memory control unit capable of detecting a two or more bit error in regard to address, in a memory control unit for controlling a memory specified by at least two addresses.

As a first configuration of the memory control unit according to the present invention to achieve the aforementioned object, the memory control unit for controlling a memory of which address is specified by at least a first address and a second address includes: a divider dividing the specified address into at least the first address and the second address; a first parity bit generator generating a first parity bit to a bit string including the first address; a second parity bit generator generating a second parity bit to a bit string including the second address; a check bit generator generating check bits for error detection when a data fed from an upper-level unit is stored into the memory, based on the data and the first parity bit and the second parity bit respectively corresponding to the first address and the second address specified as a write address of the data, so as to store the check bits into the memory, and generating check bits for error detection when a data is read out from the memory, based on the data read out from the memory, and the first parity bit and the second parity bit respectively corresponding to the first address and the second address specified as a read address of the readout data; and when the data is read out from the memory, an error detector reading out from the memory the check bits corresponding to the readout data, and detecting an error in the readout data and errors in the first address and the second address, based on the comparison between the readout check bits and the check bits generated by the check bit generator when the data is read out from the memory.

As a second configuration of the memory control unit according to the present invention, in the above first configuration, the first address and the second address are supplied to the memory through an identical signal line in a time division multiplexed manner.

As a third configuration of the memory control unit according to the present invention, in the above second configuration, the first address is a row address, and the second address is a column address.

As a fourth configuration of the memory control unit according to the present invention, in the above third configuration, the first parity bit generator generates the first parity bit to a bit string including a bank address in addition to the row address.

As a fifth configuration of the memory control unit according to the present invention, in the above third configuration, the second parity bit generator generates the first parity bit to a bit string including a bank address in addition to the column address.

As a sixth configuration of the memory control unit according to the present invention, the memory control unit for controlling a memory, of which write address and read address are specified by a first address, a second address and a third address, includes: a divider dividing the address specified from an upper-level unit into the first address, the second address and the third address; a first parity bit generator generating a first parity bit to the first address; a second parity bit generator generating a second parity bit to the second address; a third parity bit generator generating a third parity bit to the third address; a check bit generator generating check bits for error detection when a data fed from an upper-level unit is stored into the memory, based on the data and the first parity bit, the second parity bit and the third parity bit, respectively corresponding to the first address, the second address and the third address specified as a write address of the data, so as to store the check bits into the memory, and generating check bits for error detection when a data is read out from the memory, based on the data read out from the memory, and the first parity bit, the second parity bit and the third parity bit respectively corresponding to the first address, the second address and the third address specified as a read address of the readout data; and when the data is read out from the memory, an error detector reading out from the memory the check bits corresponding to the readout data, and detecting an error in the readout data and errors in the first address, the second address and the third address, based on the comparison between the readout check bits and the check bits generated by the check bit generator when the data is read out from the memory.

As a seventh configuration of the memory control unit according to the present invention, in the above sixth configuration, the first address and the second address are supplied to the memory through an identical signal line in a time division multiplexed manner.

Further scopes and features of the present invention will become more apparent by the following description of the embodiments with the accompanied drawings.

### BRIEF DESCRIPTION OF THE DRAWINGS

FIG. 1 shows a diagram illustrating a first configuration example of a memory control unit according to an embodiment of the present invention.

FIG. 2 shows a diagram illustrating a second configuration example of a memory control unit according to an embodiment of the present invention.

FIG. 3 shows a diagram illustrating a third configuration example of a memory control unit according to an embodiment of the present invention.

FIG. 4 shows a diagram illustrating a schematic configuration of a radio communication system.

### DETAILED DESCRIPTION OF THE PREFERRED EMBODIMENTS

The preferred embodiments of the present invention are described hereinafter referring to the charts and drawings. However, the embodiments described below are not intended to limit the technical scope of the present invention.

According to the embodiment of the present invention, an address specified from an upper-level unit is divided into Bank address, Row address and Column address, and to the respective Row address and the Column address supplied in a time division multiplexed manner, parity bits are generated separately, and check bits are generated based on both the above parity bits and a write data (or a read data). With this, when a bit error is produced in either one of the Row address and the Column address, it is possible to detect the bit error produced in the Row address or the bit error produced in the Column address. Further, when bit errors are produced in both the Row address and the Column address, it is possible to detect as a two-bit error, although the bit producing the error cannot be identified.

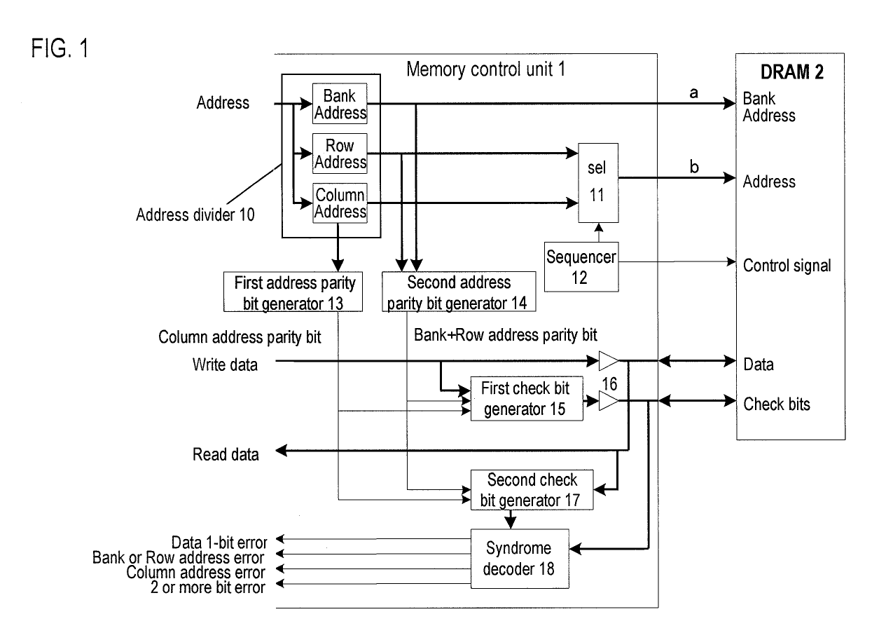

FIG. 1 shows a diagram illustrating a first configuration example of a memory control unit according to an embodiment of the present invention. An address divider 10 in a memory control unit 1 divides the address specified from an upper-level unit (not shown) into Bank address, Row address and Column address. The Bank address is independently supplied to a memory (for example, DRAM) 2 via a signal line ‘a’. Meanwhile, the Row address and the Column address are input to a selector 11, and supplied from the selector to memory 2 through an identical signal line ‘b’ in a time division multiplexed manner, under the control of a sequencer 12.

A first parity bit generator 13 generates a parity bit to the Column address (hereafter referred to as Column address parity bit).

A second parity bit generator 14 generates a parity bit to a bit string that combines the Row address with the Bank address (hereafter referred to as Bank+Row address parity bit). Accordingly, the above Bank+Row address parity bit can detect error when a one-bit error is produced in either the Row address or the Bank address, while it is not possible to detect error when one-bit errors are produced in both the Row address and the Bank address. The reason of generating the parity bit in combination of the Row address and the Bank address is that the possibility of errors being produced simultaneously in the Row address and the Bank address is low, and that it is intended to detect a bit error also in the Bank address, not only in the Row address. As described above, because the Row address and the Column address are supplied through the identical signal line, there is relatively high possibility of simultaneous errors being produced in both the Row address and the Column address, due to a signal line failure in a single point that may cause bit errors in both the Row address and the Column address. Therefore, according to the present embodiment, the parity bits are generated separately to the Row address and the Column address, respectively, and the check bits are generated to the data string that combines a data with the above parity bits.

Additionally, as will be described later, it is possible to configure to generate a parity bit to the combination of the Column address with the Bank address (a second configuration). Also, it is possible to configure to generate a parity bit independently to the Bank address (a third configuration).

At the time of write operation, address divider 10 divides a write address specified from the upper-level unit into Bank address, Row address and Column address. Also, first parity bit generator 13 generates a Column address parity bit, while second parity bit generator 14 generates a Bank+Row address parity bit.

The Column address parity bit and the Bank+Row address parity bit generated to the write address are input to a first check bit generator 15. First check bit generator 15 adds both the Column address parity bit and the Bank+Row address parity bit to the write data, so as to generate check bits. When the write data is constituted of 32 bits, seven bits are required for the above check bits. Here, the check bits constituted of seven bits can detect an error in a bit string up to 35 bits. Therefore, using seven bits without increasing the number of bits, it is possible to generate the check bits to a 34-bit data string including the Column address parity bit and the Bank+Row address parity bit, each constituted of one bit, being added to the 32-bit write data.

The check bits generated by first check bit generator 15 and the write data corresponding thereto are respectively stored in memory 2. More specifically, first, the Bank address and the Row address are output to memory 2. Then, at the subsequent timing, the Column address and the write data are output to memory 2 (as described earlier, the Row address and the Column address are supplied to memory 2 at different timing, through the identical signal line ‘b’). The write data is then written in a memory area specified by the Bank address, the Row address and the Column address having been received by memory 2.

A buffer 16 is provided to make a write operation stand by while a readout operation is in progress.

Meanwhile, in the readout operation, address divider 10 divides a read address specified from the upper-level unit into Bank address, Row address and Column address.

Also, first, parity bit generator 13 generates a Column address parity bit, while second parity bit generator 14 generates a Bank+Row address parity bit.

Based on the above each divided address, a data is read out. More specifically, when reading out the data, first, the Bank address and the Row address are output to memory 2. At the subsequent timing, the Column address is output to memory 2 (as described above, the Row address and the Column address are supplied to memory 2 at different timing, through the identical signal line ‘b’). Then, the recorded data and the check bits corresponding thereto are read out from a memory area specified by the Bank address, the Row address and the Column address having been received by memory 2.

The Column address parity bit and the Bank+Row address parity bit generated to the read address are input to a second check bit generator 17. Second check bit generator 17 adds the Column address parity bit and the Bank+Row address parity bit to the readout data, so as to generate check bits.

A syndrome decoder (error detector) 18 performed syndrome decoding, based on the check bits generate in second check bit generator 17 and check bits read out from memory 2. As a result of the syndrome decoding, syndrome decoder 18 can detect one-bit error in the data, one-bit error in the Bank+Row address parity bit, or one-bit error in the Column address parity bit. Also, it is possible to detect a two or more bit error, although it is not possible to identify the positions of the error bits.

Namely, conventionally, the parity bit included in the check bits is one bit. Therefore, when one-bit errors are produced in both the Row address and the Column address, the above parity bit comes to have a normal value, which makes it unable to detect both errors. In contrast, according to the present embodiment, even when one-bit errors are produced in both the Row address and the Column address, it is possible to detect the errors as the occurrence of a two or more bit error. Additionally, in the above case, it is not possible to identify whether the error has been produced in the Row address or the Column address, because the error occurrence positions cannot be identified.

The history of errors detected in syndrome decoder 18 is stored in a predetermined internal memory, to be used for cause analysis or error point identification (in case of one-bit error).

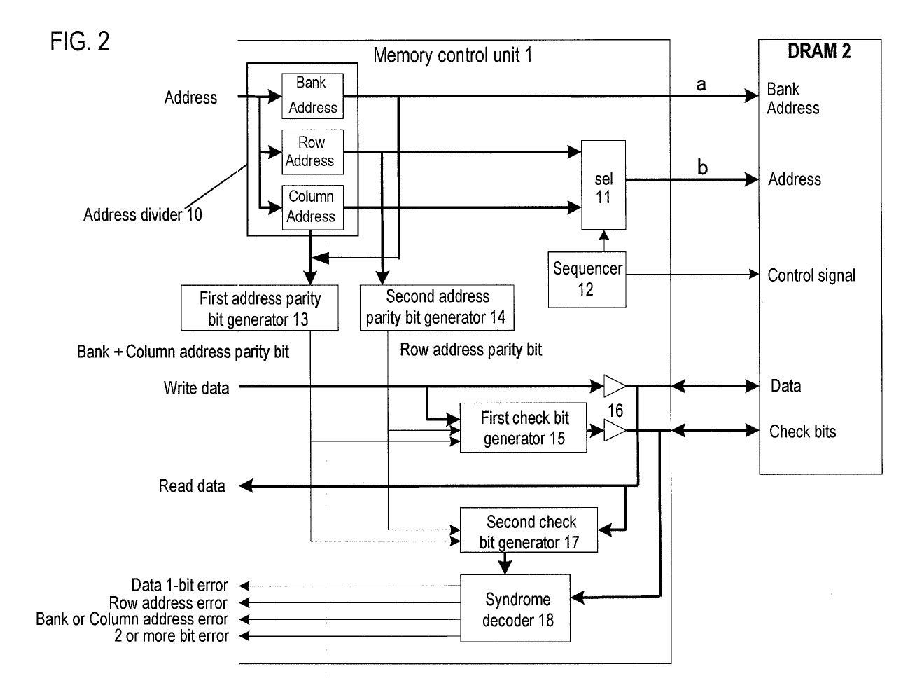

FIG. 2 shows a diagram illustrating a second configuration example of a memory control unit according to an embodiment of the present invention. In the second configuration example, as compared with the first configuration example shown in FIG. 1, first parity bit generator 13 generates a parity bit to the combination of the Column address with the Bank address (hereafter referred to as Bank+Column address parity bit), in place of the Column address parity bit. Also, second parity bit generator 14 generates a parity bit to the Row address (hereafter referred to as Row address parity bit), in place of the Bank+Row address parity bit. The operation of the second configuration example is similar to the operation of the first configuration example described above.

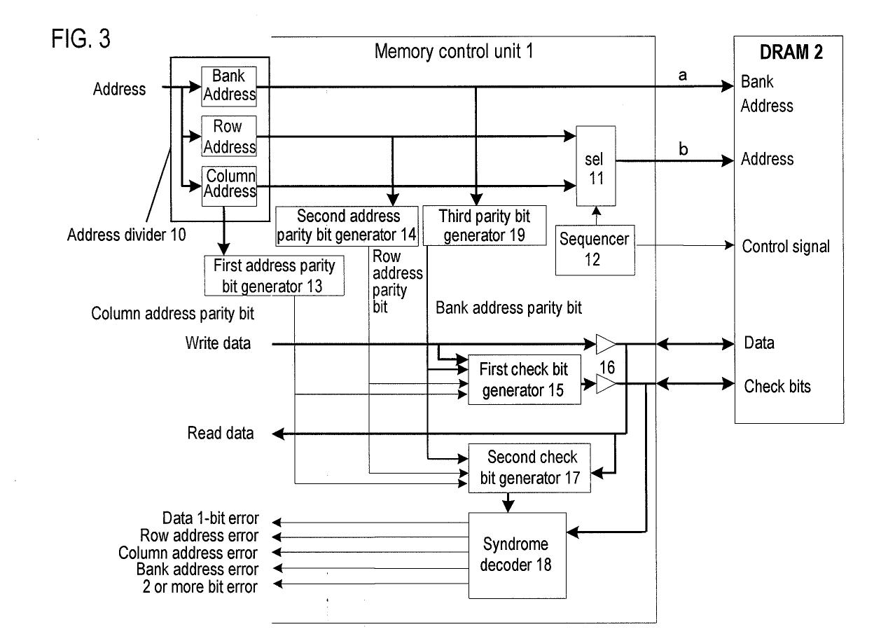

FIG. 3 shows a diagram illustrating a third configuration example of a memory control unit according to an embodiment of the present invention. In the third configuration example, as compared with the first configuration example shown in FIG. 1, there is provided a third parity bit generator 19 for generating a parity bit to the Bank address (hereafter referred to as Bank address parity bit). Instead, second parity bit generator 14 generates a Row address parity bit, in place of the Bank+Row address parity bit. In the third configuration example, when one-bit errors are produced in both the Row address and the Bank address (or when one-bit errors are produced in both the Column address and the Bank address), syndrome decoder 18 can detect error as a two or more bit error. As described earlier, by use of the check bits constituted of seven bits, error detection can be made for a data string up to 35 bits. Accordingly, even when the Bank address parity bit is added, it is not necessary to increase the number of bits in the check bits, because the bit string is constitute of 35 bits, including totally three parity bits being added to the 32-bit data string. The operation of the third configuration example is similar to the operation of the first configuration example.

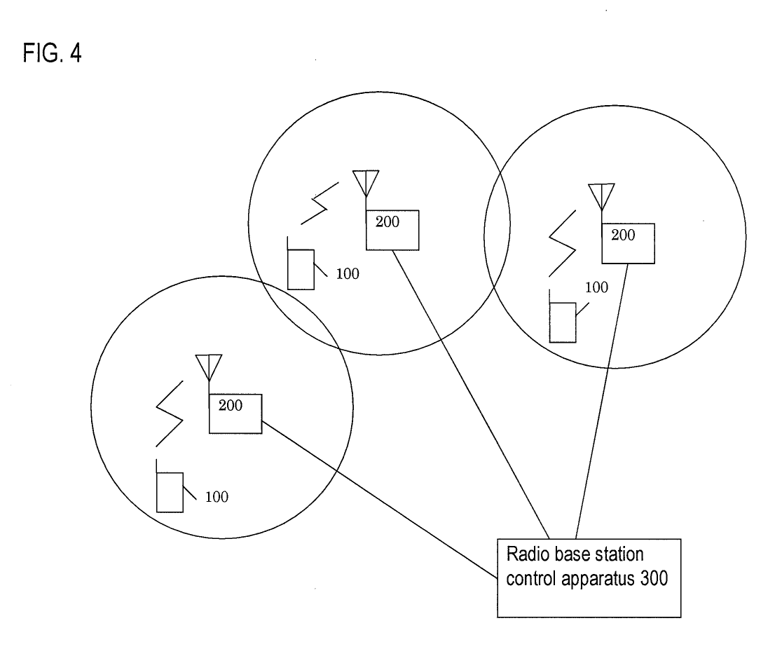

By applying the memory control unit of the above-mentioned embodiments particularly to a base station control apparatus in a radio communication system, a highly reliable radio base station control apparatus can be provided. FIG. 4 shows a diagram illustrating a schematic configuration of the radio communication system. Each radio base station 200 communicates with each radio terminal (such as mobile phone) 100 existent in the area of each radio base station, and a radio base station control apparatus 300 controls and manages a plurality of radio base stations. If a malfunction or operation suspension is produced in the radio base station control apparatus managing such the plurality of radio base stations due to an error in the memory mounted thereon, there is a risk of serious inconvenience disabling radio communication that may occur over a wide range. The memory control unit according to the present invention prevents the occurrence of such the inconvenience, thus contributing to stable operation of the base station control apparatus. Needless to say, the application of the memory control unit according to the present invention is not limited to the radio base station control apparatus. The memory control unit is also applicable to the radio base station, and also, to other communication system, control apparatus and information processing apparatus, without being limited to the radio communication system.

According to the present invention, a parity bit is generated to each of a plurality of addresses for specifying a memory area, and check bits are generated based on the above parity bit. Accordingly, error detection can be made even when errors are produced in a plurality of parity bits. In particular, the method is effective for error detection when errors are produced on the plurality of addresses due to a fault at one point of a signal line, when the plurality of addresses are supplied through an identical signal line in a time division multiplexed manner. Thus, it is possible to improve equipment reliability in which the memory control unit of the present invention is incorporated.

The foregoing description of the embodiments is not intended to limit the invention to the particular details of the examples illustrated. Any suitable modification and equivalents may be resorted to the scope of the invention. All features and advantages of the invention falling within the scope of the invention are covered by the appended claims.

What is claimed is:

1. A memory control unit for controlling a memory of which address is specified by at least a first address and a second address, comprising:
a divider dividing the specified address into at least the first address and the second address;
a first parity bit generator generating a first parity bit to a bit string including the first address;
a second parity bit generator generating a second parity bit to a bit string including the second address;
a check bit generator generating check bits for error detection when a data fed from an upper-level unit is stored into the memory, based on the data and the first parity bit and the second parity bit respectively corresponding to the first address and the second address specified as a write address of the data, so as to store the check bits into the memory, and generating check bits for error detection when a data is read out from the memory, based on the data read out from the memory, and the first parity bit and the second parity bit respectively corresponding to the first address and the second address specified as a read address of the readout data; and
an error detector, when the data is read out from the memory, reading out from the memory the check bits corresponding to the readout data, and detecting an error in the readout data and errors in the first address and the second address, based on the comparison between the readout check bits and the check bits generated by the check bit generator when the data is read out from the memory.

2. The memory control unit according to claim 1,
wherein the first address and the second address are supplied to the memory through an identical signal line in a time division multiplexed manner.

3. The memory control unit according to claim 2,
wherein the first address is a row address, and the second address is a column address.

4. The memory control unit according to claim 3,
wherein the first parity bit generator generates the first parity bit to a bit string including the row address and a bank address.

5. The memory control unit according to claim 3,
wherein the second parity bit generator generates the first parity bit to a bit string including a bank address in addition to the column address.

6. A memory control unit for controlling a memory of which write address and read address are specified by a first address, a second address and a third address, comprising:
a divider dividing the address specified from an upper-level unit into the first address, the second address and the third address;
a first parity bit generator generating a first parity bit to the first address;
a second parity bit generator generating a second parity bit to the second address;
a third parity bit generator generating a third parity bit to the third address;
a check bit generator generating check bits for error detection when a data fed from an upper-level unit is stored into the memory, based on the data and the first parity bit, the second parity bit and the third parity bit, respectively corresponding to the first address, the second address and the third address specified as a write address of the data, so as to store the check bits into the memory, and generating check bits for error detection when a data is read out from the memory, based on the data read out from the memory, and the first parity bit, the second parity bit and the third parity bit respectively corresponding to the first address, the second address and the third address specified as a read address of the readout data; and
an error detector, when the data is read out from the memory, reading out from the memory the check bits corresponding to the readout data, and detecting an error in the readout data and errors in the first address, the second address and the third address, based on the comparison between the readout check bits and the check bits generated by the check bit generator when the data is read out from the memory.

7. The memory control unit according to claim 6,
wherein the first address and the second address are supplied to the memory through an identical signal line in a time division multiplexed manner.

8. A radio base station control apparatus mounting the memory control unit according to claim 1.

9. A radio base station control apparatus mounting the memory control unit according to claim 6.
